(19) United States
(12) Patent Application Publication
(10) Pub. No.: US 2011/0121329 A1
(43) Pub. Date: May 26, 2011

(54) AC LED Structure

(75) Inventors: Ming-Hung Chen, Taiwan (CN); Shih-Yi Wen, Taiwan (CN); Jing-Yi Chen, Taiwan (CN)

(73) Assignee: Helio Optoelectronics Corporation, Zhudong Town, Hsinchu County (TW)

(21) Appl. No.: 13/003,714

(22) PCT Filed: Aug. 6, 2008
(86) PCT No.: PCT/CN2008/001432

§ 371 Date: Jan. 11, 2011

(51) Int. Cl. H01L 27/15

(52) U.S. Cl. 257/91; 257/88; 257/E27.12

(57) ABSTRACT

An AC LED structure includes an insulating substrate, an LED set, a first metal layer and a second metal layer. The LED set has a first light-emitting diode and a second light-emitting diode, which are deposited on the insulating substrate and insulated from each other. The first metal layer and the second metal layer commonly have a first profile and serve to electrically connect the first light-emitting diode and the second light-emitting diode in an inverse parallel connection. In virtue of the first metal layer and the second metal layer of the first profile deposited on the first light-emitting diode and the second light-emitting diode, the LED set is allowed to be connected in series or in parallel with another LED set according to practical needs, so as to be able to endure high current density or high voltage operation.

### CROSS-REFERENCE TO RELATED APPLICATIONS

This application is a 35 USC 371 application of PCT/CN2008/001432 filed on Aug. 6, 2008, published as Pub. No. WO2010/015106. The content of the specification is incorporated herein by reference.

### BACKGROUND OF THE INVENTION

1. Technical Field

The present invention relates to alternating-current light-emitting diode structures, and more particularly, to an AC LED structure suitable for high current density/high voltage operation.

2. Description of Related Art

A known light-emitting device disclosed in Taiwan Patent No. I280672 titled “LIGHT-EMITTING DEVICE HAVING LIGHT-EMITTING ELEMENTS” recites forming multiple GaN units on insulating substrate as LED elements in the manner that these LED elements are arranged into a binary arrangement on the insulating substrate, thereby connecting the LED elements serially into several LED sets, wherein two adjacent LED sets are connected to electrodes with opposite polarities. By arranging the LED sets into a tortuous shape, the device may be driven by high driving voltage and low driving current. In addition, due to the opposite-polarity connection of the LED sets, the device may be powered by an alternating-current source.

However, since the multiple LED elements on the insulating substrate are electrically connected to each other and to the electrodes through internal wires, the numerous wires are labyrinthine in the light-emitting device. During operation of the light-emitting device, these internal wires are likely to be melted and broken by current of high density. Further, when one of the LED sets operates forward, another is receiving reverse voltage, and tends to have leakage current.

Moreover, while connecting the LED elements, the internal wires shadow a considerable part of the light-emitting area of the LED elements. Even when more LED elements are provided on the insulating substrate with attempt to improve light extraction, the shadowed light-emitting area nevertheless limits the illumination of the light-emitting device.

In view of the shortcomings of the existing light-emitting devices, the inventor of the present invention has, with his years of abundant experience an professionalism in designing and producing LED products, applied relevant theories to actively research and innovate in expectation to create a novel AC LED structure that surpasses existing light-emitting devices and is more applicable. After repeated researches, designs, tests and modifications, the present invention of practical value is herein presented.

### SUMMARY OF THE INVENTION

A primary objective of the present invention is to overcome defects of exiting light-emitting devices by providing a novel AC LED structure. The technical issue to be addressed is to minimize the internal wires that may shadow the light-emitting area of the AC LED structure.

Another objective of the present invention is to provide an AC LED structure, that uses a first metal layer and a second metal layer to electrically connect a first light-emitting diode and a second light-emitting diode of an LED set in an inverse parallel connection, so that the LED set is allowed to be connected in series or in parallel with another LED set according to practical needs, thereby improving the applicability of the AC LED structure.

To achieve the objectives and to address the technical issues of the present invention, the following technical scheme is adopted. According to the present invention, an AC light-emitting diode structure comprises an insulating substrate; at least one LED set that has a first light-emitting diode and a second light-emitting diode, wherein the first light-emitting diode and the second light-emitting diode are deposited on the insulating substrate and insulated from each other; a first metal layer having a first profile and comprising a first end and a second end, wherein the first end is deposited on a first transparent conductive layer of the first light-emitting diode, and the second end is deposited on a second N-type layer of the second light-emitting diode; and a second metal layer having the first profile and comprising a third end and a fourth end, wherein the third end is deposited on a second transparent conductive layer of the second light-emitting diode, and the fourth end is deposited on a first N-type layer of the first light-emitting diode.

To further achieve the objectives and to further address the technical issues of the present invention, the following technical measures may be implemented.

In the foregoing AC light-emitting diode structure, the insulating substrate is a sapphire substrate.

In the foregoing AC light-emitting diode structure, the first light-emitting diode has the first N-type layer being deposited in a first region on the insulating substrate; a first active layer being deposited on a part of the first N-type layer; a first P-type layer being deposited on the first active layer; and the first transparent conductive layer being deposited on the first P-type layer, while the second light-emitting diode comprises: the second N-type layer being deposited in a second region on the insulating substrate; a second active layer being deposited on a part of the second N-type layer; a second P-type layer being deposited on the second active layer; and the second transparent conductive layer being deposited on the second P-type layer.

In the foregoing AC light-emitting diode structure, each of the first active layer and the second active layer has a U-like shape with an opening facing the U-like shape of the other active layer, and the first active layer and the second active layer allow the first N-type layer and the second N-type layer to be partially exposed.

The foregoing AC light-emitting diode structure further has an insulating layer, which extends along laterals of the first N-type layer and the second N-type layer.

In the foregoing AC light-emitting diode structure, the insulating layer extends along laterals of the first light-emitting diode and the second light-emitting diode.

The foregoing AC light-emitting diode structure further has a first pad and a second pad, wherein the first pad is formed on the first end, and the second pad is formed on the third end.

The foregoing AC light-emitting diode structure further has a first pad and a second pad, wherein the first pad is formed on the second end, and the second pad is formed on the fourth end.

In the foregoing AC light-emitting diode structure, the first metal layer and the second metal layer are provided at peripheries of the first light-emitting diode and the second light-emitting diode.

In the foregoing AC light-emitting diode structure, each of the second end and the fourth end has an end located on a central axis of the first and second light-emitting diodes.

In the foregoing AC light-emitting diode structure, adjacent portions of the first metal layer and the second metal layer are spaced equidistantly from each other.

In the foregoing AC light-emitting diode structure, each of the second end and the fourth end has an end in a semicircular shape.

In the foregoing AC light-emitting diode structure, the first profile is a scoop-like shape or a half-S shape or one selected from the group consisting of a square, a round and any combination thereof.

As compared with prior art, the present invention has obvious benefits and profitable effects. To achieve the foregoing objectives, the present invention provides an AC light-emitting diode structure that comprises: an insulating substrate; at least one LED set that has a first light-emitting diode and a second light-emitting diode, wherein the first light-emitting diode and the second light-emitting diode are deposited on the insulating substrate and insulated from each other; a first metal layer having a first profile and comprising a first end and a second end, wherein the first end is deposited on a first transparent conductive layer of the first light-emitting diode, and the second end is deposited on a second N-type layer of the second light-emitting diode; and a second metal layer having the first profile and comprising a third end and a fourth end, wherein the third end is deposited on a second transparent conductive layer of the second light-emitting diode, and the fourth end is deposited on a first N-type layer of the first light-emitting diode.

With the above technical schemes, the AC light-emitting diode structure of the present invention has at least the following benefits and profitable effects:

1. Since the internal wires are minimized, the light-emitting area of the AC light-emitting diode structure is unlikely to be shadowed.

2. By the first metal layer and the second metal layer that electrically connect the first light-emitting diode and the second light-emitting diode of the LED set in an inverse parallel connection, the LED set is allowed to be connected in series or in parallel with another LED set according to practical needs, thereby improving the applicability of the AC light-emitting diode structure.

### BRIEF DESCRIPTION OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is an exploded view of an AC light-emitting diode structure according to the present invention;

FIG. 2 is a perspective view of the AC light-emitting diode structure according to the present invention;

FIG. 3 is an equivalent-circuit diagram of the AC light-emitting diode structure according to the present invention;

FIG. 4 is a cross-sectional view taken along Line A-A of FIG. 2;

FIG. 5 is a first aspect of the AC light-emitting diode structure according to the present invention;

FIG. 6 is a second aspect of the AC light-emitting diode structure according to the present invention;

FIG. 7 is a third aspect of the AC light-emitting diode structure according to the present invention;

FIG. 8 is a fourth aspect of the AC light-emitting diode structure according to the present invention;

FIG. 9A is a first equivalent circuit of the AC light-emitting diode structure according to the present invention; and

FIG. 9B is a second equivalent circuit of the AC light-emitting diode structure according to the present invention.

### DETAILED DESCRIPTION OF THE INVENTION

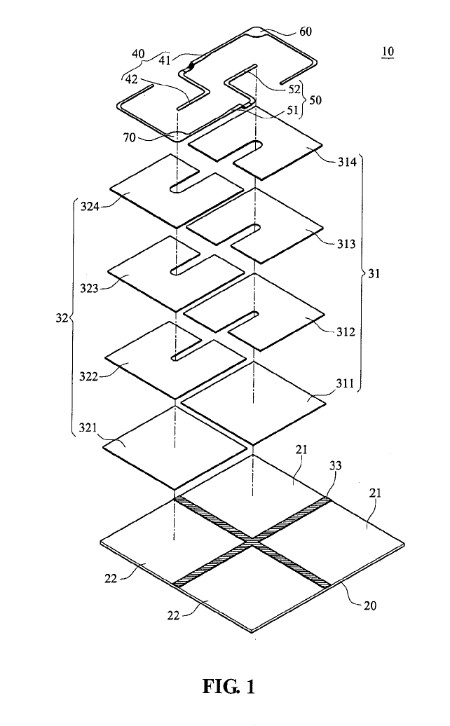

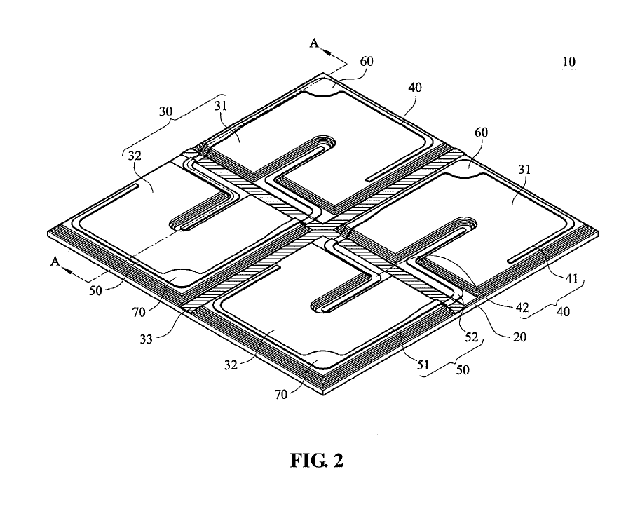

As shown in FIG. 1 and FIG. 2, the present embodiment is an AC LED (light-emitting diode) structure 10, which comprises: an insulating substrate 20, at least one LED set 30, a first metal layer 40, and a second metal layer 50.

The insulating substrate 20 may be a sapphire substrate or any other insulating substrate suitable for LED fabrication. The insulating substrate 20 may be divided into plural regions for receiving multiple LED sets 30.

The LED sets 30 are deposited on the insulating substrate 20, and each said LED set 30 has a first light-emitting diode 31 and a second light-emitting diode 32. The first light-emitting diode 31 and the second light-emitting diode 32 are insulated and separated from each other while the LED sets 30 are insulated and separated from each other. For ensuing insulation between the first light-emitting diode 31 and the second light-emitting diode 32, an insulating layer 33 may be additionally provided between the first light-emitting diode 31 and the second light-emitting diode 32, so as to prevent leakage current.

As shown in FIG. 1, the first light-emitting diode 31 has a first N-type layer 311, a first active layer 312, a first P-type layer 313, and a first transparent conductive layer 314. Similarly, the second light-emitting diode 32 has a second N-type layer 321, a second active layer 322, a second P-type layer 323, and a second transparent conductive layer 324.

The first light-emitting diode 31 has the first N-type layer 311 deposited in a first region 21 of the insulating substrate 20, and the second light-emitting diode 32 has the second N-type layer 321 deposited in a second region 22 of the insulating substrate 20, while the first region 21 and the second region 22 are adjacent to each other, so as to be electrically connected to the first light-emitting diode 31 and the second light-emitting diode 32.

The first active layer 312 and the second active layer 322 may each be of a U-like shape with an opening facing that of the other, and are deposited on the first N-type layer 311 and the second N-type layer 321, respectively, so that the first N-type layer 311 and the second N-type layer 321 are partially exposed outside the first active layer 312 and the second active layer 322.

The first P-type layer 313 and the second P-type layer 323 are deposited on the first active layer 312 and the second active layer 322, respectively. The first transparent conductive layer 314 and the second transparent conductive layer 324 are deposited on the first P-type layer 313 and the second P-type layer 323, respectively. The insulating layer 33 may be provided along edges of the first N-type layer 311 and the second N-type layer 321, so as to completely insulate the first light-emitting diode 31 from the second light-emitting diode 32.

As shown in FIG. 1 and FIG. 2, the first metal layer 40 has a first profile that includes a first end 41 and a second end 42. The first metal layer 40 has the first end 41 deposited on the first transparent conductive layer 314 of the first light-emitting diode 31, and has the second end 42 deposited on the second N-type layer 321 of the second light-emitting diode 32.

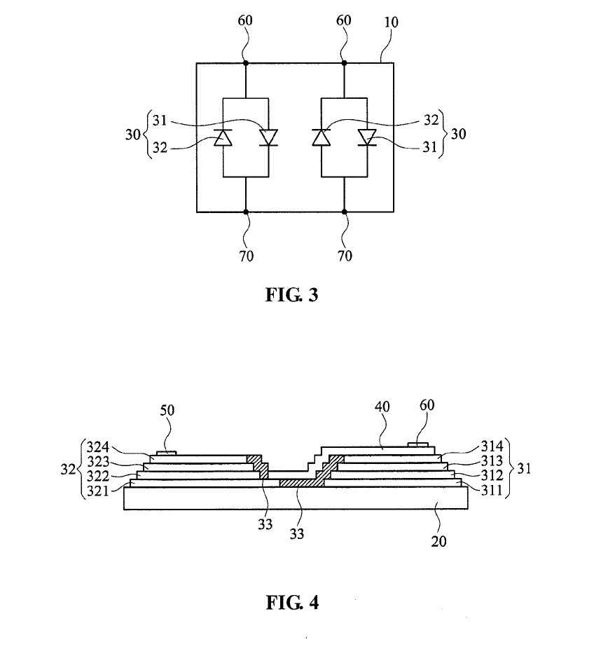

The second metal layer 50 is also in the first profile, and arranged opposite to the first metal layer 40. The second metal layer 50 has a third end 51 and a fourth end 52, wherein the third end 51 is deposited on the second transparent conductive layer 324 of the second light-emitting diode 32 while the fourth end 52 is deposited on the first N-type layer 311 of the first light-emitting diode 31. With the provision of the first metal layer 40 and the second metal layer 50, the first light-emitting diode 31 and the second light-emitting diode 32 are electrically connected, and the first light-emitting diode 31 and second light-emitting diode 32 are in an inverse parallel connection. An equivalent circuit diagram thereof is as shown in FIG. 3.

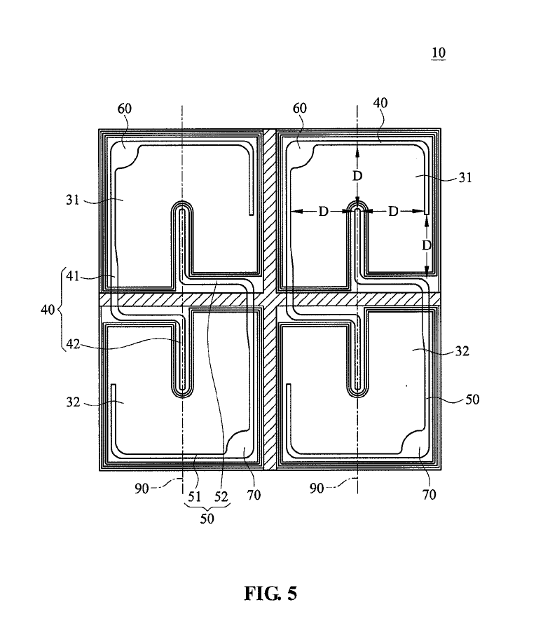

Referring to FIG. 4, in order to prevent short circuit caused by the use of the first metal layer 40 for the electrical connection between the first light-emitting diode 31 and the second light-emitting diode 32, the insulating layer 33 may be extended to cover laterals of the first and second light-emitting diodes 31, 32, so as to achieve insulation between the first and second light-emitting diodes 31, 32 and the first metal layer 40. Similarly, the insulating layer 33 may be extended to cover laterals of the first and second light-emitting diodes 31, 32, so as to achieve insulation between the first and second light-emitting diodes 31, 32 and the second metal layer 50 that electrically connects the first light-emitting diode 31 and the second light-emitting diode 32, thereby preventing short circuit.

As shown in FIG. 5, for allowing electrical connection between the AC LED structure 10 and an external circuit 80, the AC LED structure 10 may further has a first pad 60 and a second pad 70. The first pad 60 may be formed on the first end 41 of the first metal layer 40, and the second pad 70 may be formed on the third end 51 of the second metal layer 50. Alternatively, the first pad 60 may be formed on the second end 42 of the first metal layer 40, and the second pad 70 may be formed on the fourth end 52 of the second metal layer 50.

Thereby, the AC LED structure 10 can be electrically connected to the external circuit 80 through the first pad 60 and the second pad 70, respectively, for receiving an alternating current to power the first light-emitting diode 31 and the second light-emitting diode 32. However, for example, when the first light-emitting diode 31 is on, the first end 41 of the first metal layer 40 acts as a current transmitter while the fourth end 52 of the second metal layer 50 acts as a current receiver that receives the current transmitted by the first end 41 of the first metal layer 40, thereby driving the first light-emitting diode 31 to light.

As shown in FIG. 5, for supporting the first metal layer 40 and the second metal layer 50 to receive the current effectively, and for allowing the current to be evenly distributed over the first light-emitting diode 31 and the second light-emitting diode 32, the first profile of the first and the second metal layers 40, 50 may be a scoop-like shape encircling peripheries of the first and second light-emitting diodes 31, 32, so as to enlarge the light extraction area of the first and second light-emitting diodes 31, 32.

Additionally, the second end 42 of the first metal layer 40 and the fourth end 52 of the second metal layer 50 have their one ends located on a central axis 90 of the first and second light-emitting diodes 31, 32. The adjacent portions of the first metal layer 40 and the second metal layer 50 are spaced equidistantly by a distance D. This ensures the diffusion of the current between the metal layers has the constant distance D, thereby allowing the current to diffuse from one metal layer to the other in a constant speed, and lighting up the first and second light-emitting diodes 31, 32 evenly.

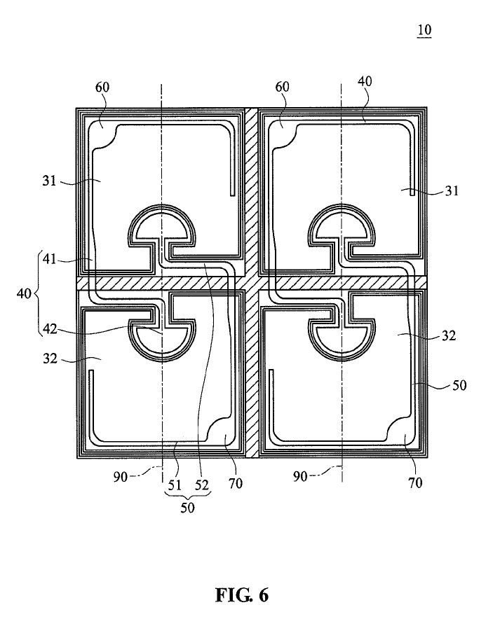

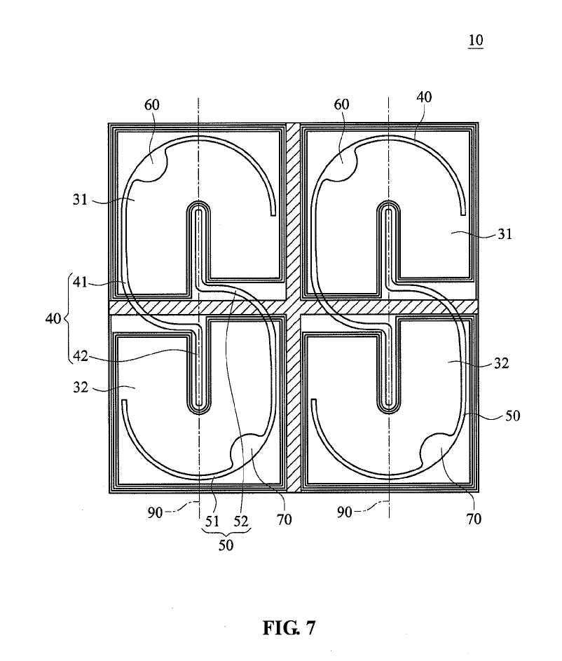

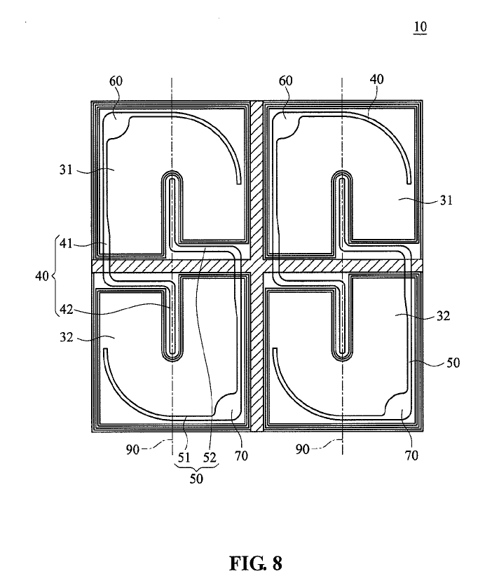

Referring to FIG. 6, the second end 42 of the first metal layer 40 and the fourth end 52 of the second metal layer 50 may have their ends commonly formed as a semicircular shape. Alternatively, as shown in FIG. 7, the first profile of the first and second metal layers 40, 50 may be a half-S shape. Or, as shown in FIG. 8, the first profile may be any selected from the group consisting of a square, a round and any combination thereof.

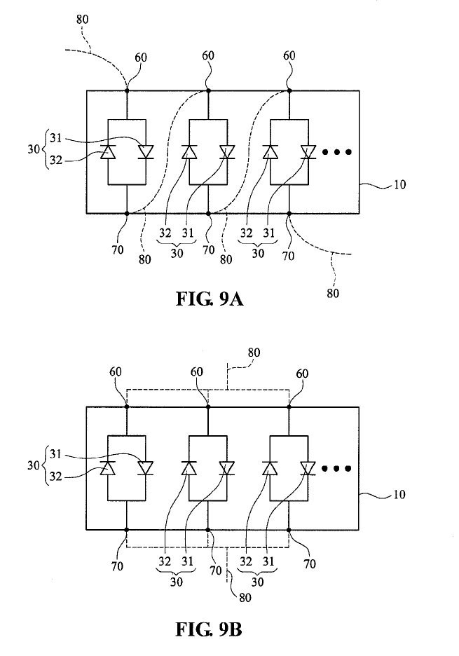

As shown in FIG. 9A and FIG. 9B, by implementing the present embodiment, the insulating substrate 20 may be provided with multiple LED sets 30, and the multiple LED sets 30 may be connected in series or in parallel by means of the external circuit 80, so that the AC LED structure 10 may be endurable to high current density or high voltage operation according to the practical needs. Furthermore, since the number of the necessary internal wires is substantially reduced, the problem that the internal wires shadows the light-emitting area of the AC LED structure 10 can be eliminated, thereby improving the illumination of the AC LED structure 10.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. An AC LED structure, comprising:
an insulating substrate;
at least one LED set that has a first light-emitting diode and a second light-emitting diode, wherein the first light-emitting diode and the second light-emitting diode are deposited on the insulating substrate and insulated from each other;
a first metal layer having a first profile and comprising a first end and a second end, wherein the first end is deposited on a first transparent conductive layer of the first light-emitting diode, and the second end is deposited on a second N-type layer of the second light-emitting diode; and
a second metal layer having the first profile and comprising a third end and a fourth end, wherein the third end is deposited on a second transparent conductive layer of the second light-emitting diode, and the fourth end is deposited on a first N-type layer of the first light-emitting diode.

2. The AC LED structure of claim 1, wherein the insulating substrate is a sapphire substrate.

3. The AC LED structure of claim 1, wherein the first light-emitting diode comprises:
the first N-type layer being deposited in a first region on the insulating substrate;
a first active layer being deposited on a part of the first N-type layer;
a first P-type layer being deposited on the first active layer; and
the first transparent conductive layer being deposited on the first P-type layer, while the second light-emitting diode comprises:
the second N-type layer being deposited in a second region on the insulating substrate;
a second active layer being deposited on a part of the second N-type layer;
a second P-type layer being deposited on the second active layer; and
the second transparent conductive layer being deposited on the second P-type layer.

4. The AC LED structure of claim 3, wherein either of the first active layer and the second active layer has a U-like shape with an opening facing the U-like shape of the other active layer, and the first active layer and the second active layer allow the first N-type layer and the second N-type layer to be partially exposed.

5. The AC LED structure of claim 3, further comprising an insulating layer, which extends along laterals of the first N-type layer and the second N-type layer.

6. The AC LED structure of claim 5, wherein the insulating layer extends along laterals of the first light-emitting diode and the second light-emitting diode.

7. The AC LED structure of claim 1, further comprising a first pad and a second pad, wherein the first pad is formed on the first end, and the second pad is formed on the third end.

8. The AC LED structure of claim 1, further comprising a first pad and a second pad, wherein the first pad is formed on the second end, and the second pad is formed on the fourth end.

9. The AC LED structure of claim 1, wherein the first metal layer and the second metal layer are provided at peripheries of the first light-emitting diode and the second light-emitting diode.

10. The AC LED structure of claim 1, wherein each of the second end and the fourth end has an end located on a central axis of the first and second light-emitting diodes.

11. The AC LED structure of claim 1, wherein adjacent portions of the first metal layer and the second metal layer are spaced equidistantly from each other.

12. The AC LED structure of claim 1, wherein each of the second end and the fourth end has an end in a semicircular shape.

13. The AC LED structure of claim 1, wherein the first profile is a scoop-like shape or a half-S shape or one selected from the group consisting of a square, a round and any combination thereof.
